(19) United States
(12) Patent Application Publication
(10) Pub. No.: US 2010/0009551 A1
(43) Pub. Date: Jan. 14, 2010

(54) SEMICONDUCTOR DEVICE AND METHOD FOR MANUFACTURING THE SAME

(75) Inventor: Masanori INOUE, Tokyo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: MITSUBISHI ELECTRIC CORPORATION, Chiyoda-ku (JP)

(21) Appl. No.: 12/565,461

(22) Filed: Sep. 23, 2009

Related U.S. Application Data
(62) Division of application No. 11/678,384, filed on Feb. 23, 2007.

(30) Foreign Application Priority Data
Oct. 3, 2006 (JP) 2006-272062

(51) Int. Cl. H01L 21/26

(52) U.S. Cl. 438/798; 257/E21.328

(57) ABSTRACT

A p-n junction is formed at the interface of a low-concentration n-type impurity layer and a p-type diffusion region in the vicinity of the upper major surface of an n-type semiconductor substrate of a semiconductor device. A mask composed of an absorber is placed on the upper major surface of the semiconductor device, and electron beams are radiated. Thereafter, heat treatment is conducted. As a result, the peak of the crystal lattice defect densities is present in the vicinity of the upper major surface of the n-type semiconductor substrate, and the crystal lattice defect densities are decreasingly distributed toward the lower major surface. Thereby, a semiconductor device that can minimize the variation of the breakdown voltage characteristics of the p-n junction of the diode, and can control the optimum carrier lifetime can be obtained.

### CROSS-REFERENCE TO RELATED APPLICATIONS

This application is a divisional of U.S. patent application Ser. No. 11/678,384, filed Feb. 23, 2007, and claims priority to Japanese Patent Application No. 2006-272062, filed Oct. 3, 2006. The entire contents of these applications are incorporated herein by reference in their entirety.

### BACKGROUND OF THE INVENTION

1. Field of the Invention

The present invention relates to a semiconductor device and a method for manufacturing the same. More specifically, the present invention relates to a semiconductor device whose characteristics and reliability are improved by introducing a carrier lifetime killer into the substrate, and a method for manufacturing the same.

2. Background Art

In a power semiconductor element, such as an insulated gate bipolar transistor (IGBT), a diode having a p-n junction is normally provided in the substrate. When the diode is in the ON state, minority carriers are injected through the p-n junction. If the minority carriers are excessive when the diode is in the OFF state, a reverse direction current is generated to increase energy loss.

To minimize the above-described energy loss, the substrate is provided with a carrier lifetime killer, such as a crystal lattice defect. The carrier lifetime killer can recombine with the minority carriers to decrease the reverse direction current, and can minimize the energy loss (for example, refer to Japanese Patent Laid-Open No. 2001-326366).

The example of methods for introducing lifetime killers into a substrate include diffusing a heavy metal, such as gold and platinum, in the substrate, or irradiating the surface of the substrate with electron beams, protons, helium or the like. In general, when crystal lattice defects are formed in a predetermined depth from the surface of the substrate, the method using proton radiation or helium radiation is suited. When crystal lattice defects are formed in the entire depth direction of the substrate, the method using electron beam radiation is suited.

In the above-described method using proton radiation or helium radiation, the breakdown voltage characteristics of the p-n junction are easily varied. In the method using electron beam radiation, the tradeoff curve of the forward voltage drop (Vf) and energy loss of the diode is deteriorated compared with the method using proton radiation or helium radiation.

### SUMMARY OF THE INVENTION

To solve the above-described problems, it is an object of the present invention to provide a semiconductor device wherein the variation of the breakdown voltage characteristics of the p-n junction in a diode is minimized, and can control the optimal carrier lifetime, and a method for manufacturing the same, in a semiconductor device wherein crystal lattice defects are formed in a substrate using electron beam radiation, and a method for manufacturing the same.

According to one aspect of the present invention, a semiconductor device has a p-n junction in a semiconductor substrate and provided with crystal lattice defects that recombine with minority carriers injected through the p-n junction, wherein the crystal lattice defects are decreasingly distributed from one major surface side toward the other major surface side of the semiconductor substrate.

According to the present invention, there can be obtained a semiconductor device wherein the variation of the breakdown voltage characteristics of the p-n junction in a diode is minimized, and can control the optimal carrier lifetime, and a method for manufacturing the same, in a semiconductor device wherein crystal lattice defects are formed in a substrate using electron beam radiation, and a method for manufacturing the same.

Other and further objects, features and advantages of the invention will appear more fully from the following description.

### BRIEF DESCRIPTION OF THE DRAWINGS

FIG. 1 shows a sectional view of a semiconductor device according to First Embodiment of the present invention.

FIGS. 2-3 are sectional views for explaining a method of manufacturing the semiconductor device according to First Embodiment of the present invention.

FIG. 4 shows the relative doses of crystal lattice defects of the semiconductor device according to First Embodiment of the present invention.

FIG. 5 is sectional views for explaining a method of manufacturing the semiconductor device according to Second Embodiment of the present invention.

FIG. 6 shows the relative doses of crystal lattice defects of the semiconductor device according to Second Embodiment of the present invention.

FIGS. 7-8 show the tradeoff curves of the forward voltage drop Vf and the reverse recovery current of the diode.

FIG. 9 is sectional views for explaining a method of manufacturing the semiconductor device according to Third Embodiment of the present invention.

FIG. 10 is sectional views for explaining a method of manufacturing the semiconductor device according to Fourth Embodiment of the present invention.

### DETAILED DESCRIPTION OF THE PREFERRED EMBODIMENTS

The embodiments of the present invention will be described above referring to the drawings. In the drawings, the same or corresponding parts will be denoted by the same numerals and characters, and the description thereof will be simplified or omitted.

### First Embodiment

A semiconductor device according to the first embodiment will be described. Here, a semiconductor device having a diode of a rated element breakdown voltage of 200 V or higher, and used in railways or the like will be described.

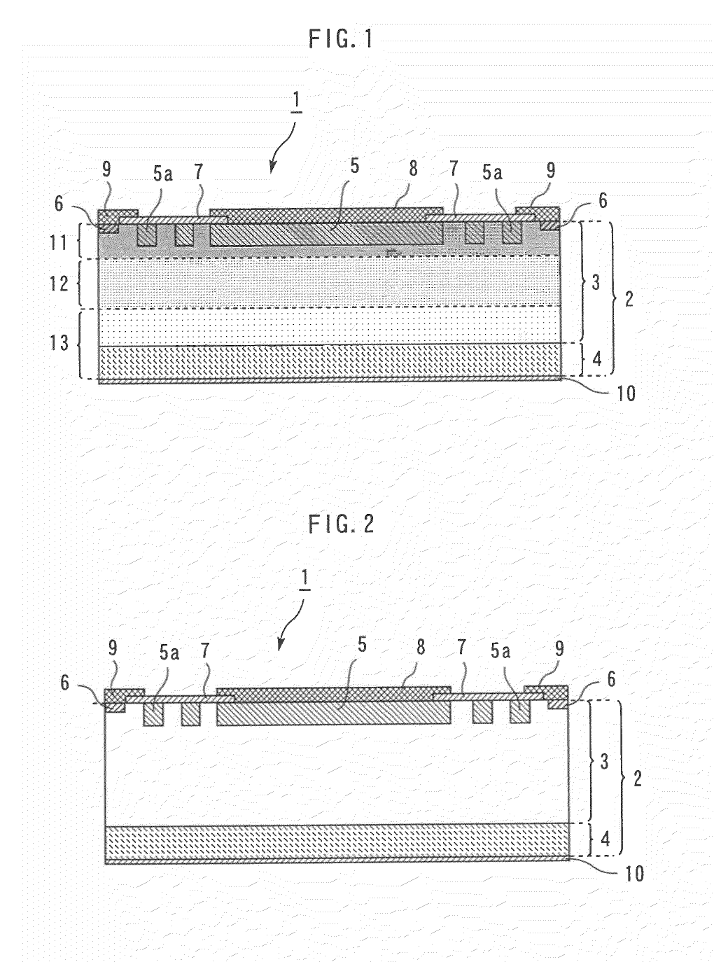

FIG. 1 shows a sectional view of the above-described semiconductor device 1. The semiconductor device 1 is formed using an n-type semiconductor substrate (hereafter simply referred to as “substrate”) 2. In the upper major surface side of the substrate 2, a low-concentration n-type impurity layer 3 containing a low-concentration n-type impurity is provided. The thickness of the layer 3 is not less than 250 μm, and the resistivity thereof is not less than 150 Ω·cm. In the lower major surface side of the substrate 2, a high-concentration n-type impurity layer 4 containing a high-concentration n-type impurity is provided so as to contact the low-concentration n-type impurity layer 3. In the vicinity of the upper major surface of the substrate 2, a p-type diffusion region 5 is selectively provided. The thickness of the region 5 is about 3 to 5 μm. Thus, a p-n junction is formed at the interface between the p-type diffusion region 5 and the low-concentration n-type impurity layer 3.

In the vicinity of the upper major surface of the substrate 2, a plurality of p-type diffusion layers 5a acting as guard rings are provided in the both outside of the p-type diffusion layer region 5. Furthermore, n-type diffusion layers 6 for imparting potentials to the low-concentration n-type impurity layer 3 are provided in the both outside of the p-type diffusion regions 5a acting as guard rings.

A phosphorus glass protective film 7 is provided so as to coat the upper surface of the p-type diffusion layer regions 5a of the guard rings and the upper surface of the end portion of the p-type diffusion region 5. An anode electrode 8 is provided on the substrate 2 so as to contact the p-type diffusion region 5. The electrode 8 is composed of aluminum or the like. Surface electrodes 9 are provided on the substrate 2 so as to contact the n-type diffusion layer 6. On the lower major surface side of the substrate 2, a cathode electrode 10 is provided so as to contact the high-concentration n-type impurity layer 4.

As described above, the anode electrode 8 is provided on the upper surface side of the substrate 2 so as to contact the p-type diffusion region 5. The p-type diffusion region 5 forms a p-n junction at the interface with the low-concentration n-type impurity layer 3. Furthermore, the low-concentration n-type impurity layer 3 is electrically connected to the high-concentration n-type impurity layer 4, and the high-concentration n-type impurity layer 4 is connected to the cathode electrode 10. Thus, a diode wherein the anode electrode 8 side acts as the anode, and the cathode electrode 10 side acts as the cathode is constituted.

Here, when a forward direction voltage of a predetermined value or higher is applied between the anode electrode 8 and the cathode electrode 10, the above-described diode becomes in the ON state, and a current flows in the forward direction. At this time, minority carriers are injected through the above-described p-n junction. Specifically, electrons are injected into the p-type diffusion region 5, and holes are injected into the low-concentration n-type impurity layer 3. When the diode becomes in the OFF state, if the quantity of the injected minority carriers is small, these minority carriers are recombined with majority carriers and disappear. However, if the minority carriers are excessively injected, part of minority carriers do not disappear, a reverse direction current is generated by the minority carriers that have not disappeared. If the current becomes large, reverse recovery loss increases.

In the semiconductor device 1 shown in FIG. 1, to minimize the above-described loss, crystal lattice defects (lifetime killers) for recombining with minority carriers are formed. These crystal lattice defects are decreasingly distributed from the upper major surface side toward the lower major surface side of the substrate 2. When the regions in the substrate 2 are named as a first region 11, a second region 12, and a third region 13 sequentially from the upper major surface side toward the lower major surface side, the crystal lattice defect density is highest in the first region 11, and is abated in the order of the second region 12 and the third region 13. In each region, the crystal lattice defects are distributed so that the crystal lattice defect density decreases from the upper surface side toward the lower surface side of the substrate 2.

Specifically, the density of the crystal lattice defects formed in the substrate 2 is highest in the vicinity of the upper major surface of the substrate 2, and is decreased toward the lower major surface. In other words, the depth of the peak of the crystal lattice defect density can be in the vicinity of the upper major surface of the substrate 2. Thereby, compared with the case wherein the above-described depth of the peak is at a predetermined depth from the upper major surface of the substrate 2, the variation of the distribution of the lifetime killers can be suppressed. Therefore, change in the breakdown voltage characteristics of the p-n junction provided in the substrate 2, or change in the breakdown voltage leakage characteristics can be suppressed.

Next, a method for manufacturing the semiconductor device 1 shown in FIG. 1 will be described. First, as shown in FIG. 2, a low-concentration n-type impurity layer 3 is formed on the upper major surface of the substrate 2, and a high-concentration n-type impurity layer 4 is formed on the lower major surface of the substrate 2. Then, a p-type diffusion layer region 5, p-type diffusion layer regions 5a of guard rings, n-type diffusion layer 6, a phosphorus glass protective film 7, and anode electrode 8, and a surface electrode 9 are formed in the vicinity of the upper major surface of the substrate 2. Further, a cathode electrode 10 is formed on the lower major surface side of the substrate 2. As a result, a semiconductor device 1 wherein a p-n junction is formed at the interface between the p-type diffusion layer region 5 and the low-concentration n-type impurity layer 3 in the vicinity of the upper major surface of the substrate 2 can be obtained.

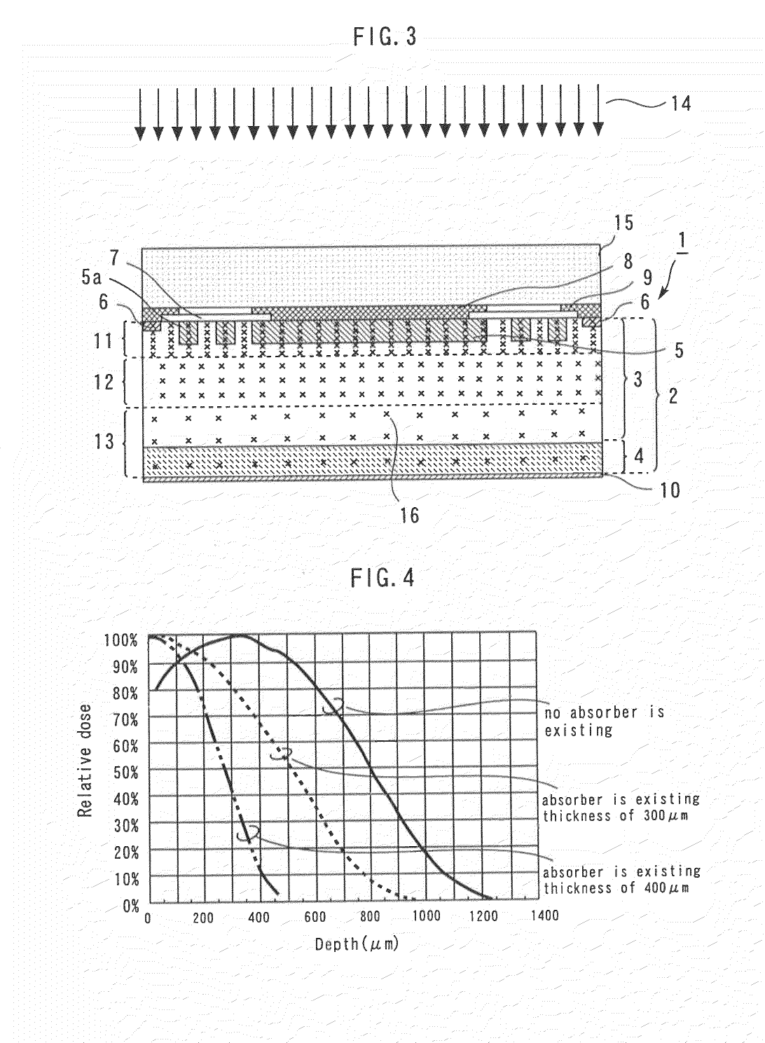

Next, as shown in FIG. 3, a mask 15 composed of an absorber that absorbs electron beams is placed on the upper major surface of the substrate 2, and electron beams 14 are radiated through the mask 15 onto the upper major surface of the substrate 2. As the above-described absorber, an Si substrate (specific gravity: 2.33) of a thickness of about 300 to 400 μm, aluminum or the like is used. The accelerated energy of electron beam radiation is a value larger than 500 keV. Here, the accelerated energy is 750 keV and the dose is 8×10¹⁴ cm⁻². As a result, crystal lattice defects 16 are formed in the substrate 2.

At this time, when the regions in the substrate 2 are named as a first region 11, a second region 12, and a third region 13 sequentially from the upper major surface side toward the lower major surface side, crystal lattice defects are formed so that the crystal lattice defect density is highest in the first region 11, and is abated in the order of the second region 12 and the third region 13. In each region, crystal lattice defects are formed so that the crystal lattice defect density decreases from the upper major surface side toward the lower major surface side of the substrate 2.

Next, the semiconductor device 1 shown in FIG. 3 is heat-treated. For example, heat treatment if performed in a nitrogen atmosphere at 340° C. for about 90 minutes. As a result, crystal lattice defects formed in the substrate 2 are stabilized, and the structure shown in FIG. 1 is obtained.

Next, the effect of placing the mask 15 on the upper major surface of the substrate 2 and performing electron beam radiation will be described. The distributions of the crystal lattice defects formed in the substrate 2 were compared for the cases wherein the mask 15 was placed and not placed on the upper major surface of the substrate 2. FIG. 4 shows the relative doses of crystal lattice defects (relative densities of defects when the peak value is expressed as 100%) to the depths from the upper major surface of the substrate 2 when the thickness of the absorber was 300 μm, 400 μm, and mask 15 was not placed. The accelerated energy of electron beam radiation was 750 keV in all the cases.

As shown in FIG. 4, when the mask 15 was not placed, the relative dose had the peak at the depth of about 300 to 350 μm from the upper major surface of the substrate 2, and the relative dose gradually decreased with increase in the depth. Whereas, when electron beam radiation was performed after placing the mask 15, in either absorber thickness of 300 μm or 400 μm, the peak of the relative dose was present in the vicinity of the upper major surface of the substrate 2. The relative dose was gradually decreased with increase in the depth from the upper major surface of the substrate 2.

From these results, the peak of the crystal lattice defect densities can be in the vicinity of the upper major surface of the substrate 2 by placing a mask composed of an absorber having a thickness of about 300 μm to 400 μm on the upper major surface of the substrate 2 and radiating electron beams. Thereby, compared with the case without placing the above-described mask, the variation of the breakdown voltage characteristics of the p-n junction by the p-type diffusion layer region 5 and the low-concentration n-type impurity layer 3 can be minimized, and the carrier lifetime can be adequately controlled.

According to the semiconductor device and the method for manufacturing the same of the first embodiment, the variation of the breakdown voltage characteristics of the p-n junction formed in the substrate can be minimized, and the semiconductor device enabling the adequate control of carrier lifetime and the method for manufacturing the same can be obtained.

### Second Embodiment

A method for manufacturing a semiconductor device according to the second embodiment will be described. Here, the description will be focused on the aspects different from the first embodiment.

In the same manner as in the first embodiment, a semiconductor device 1 wherein a p-n junction is provided at the interface between a p-type diffusion layer region 5 and a low-concentration n-type impurity layer 3 in the vicinity of the upper major surface of a substrate 2 (refer to FIG. 2).

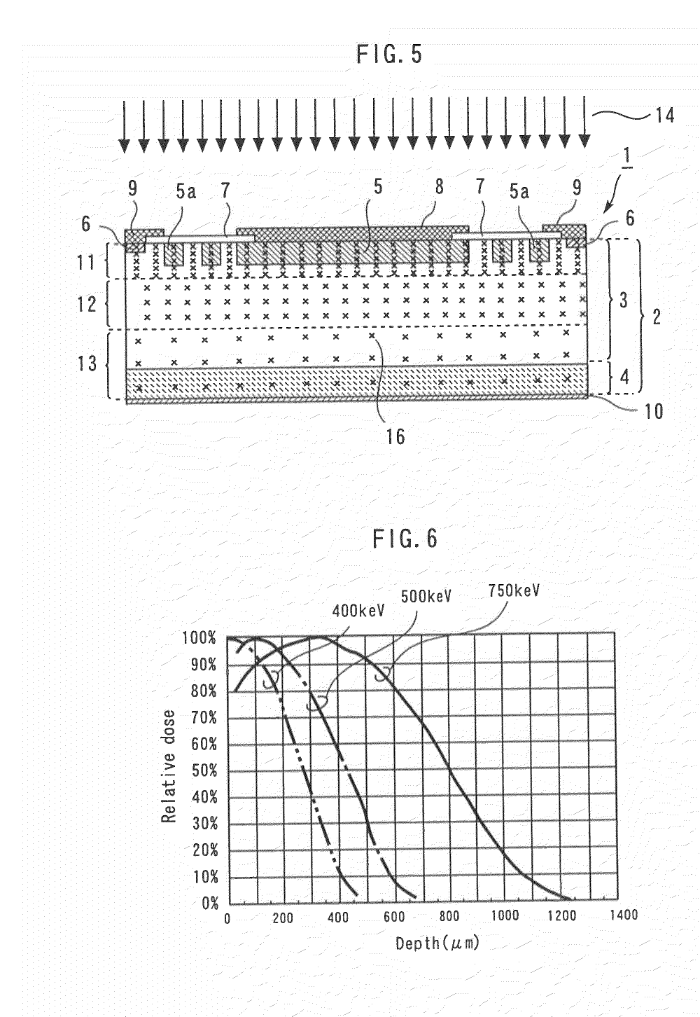

Next, as shown in FIG. 5, electron beams are radiated onto the upper major surface of the substrate 2, and crystal lattice defects 16 are formed in the substrate 2. At this time, the accelerated energy of electron-beam radiation is within a range between 400 and 500 keV. For example, electron-beam radiation of an accelerated energy of 400 keV and a dose of 3×10¹⁵ cm⁻² is performed. Alternatively, electron-beam radiation of an accelerated energy of 500 keV and a dose of 1×10¹⁵ cm⁻² is performed. In the first embodiment, electron-beam radiation was performed after placing a mask composed of an absorber on the upper major surface of the substrate 2. While in the second embodiment, electron-beam radiation was performed without placing the above-described mask on the upper major surface of the substrate 2.

Then, in the same manner as in the first embodiment, the semiconductor device 1 shown in FIG. 5 is heat-treated. Thereby, the crystal lattice defects 16 formed in the substrate 2 are stabilized, and a structure equivalent to the structure shown in FIG. 1 can be obtained.

Next, the effect of electron-beam radiation shown in FIG. 5 will be described. FIG. 6 shows the relative doses of the crystal lattice defects formed in the substrate 2 when electron-beam radiations of accelerating energies of 400 keV, 500 keV, and 750 keV were performed without placing a mask composed of an absorber on the upper major surface of the substrate 2.

When the accelerating energy is 750 keV, the peak of the relative dose is present at a depth of 300 to 400 μm from the upper major surface of the substrate 2. While when the accelerating energy is 400 keV, peak of the relative dose is present in the vicinity of the upper major surface of the substrate 2. When the accelerating energy is 500 keV, the peak of the relative dose is present at a depth of about 100 μm from the upper major surface of the substrate 2. Specifically, by making the accelerating energy of electron-beam radiation within a range between 400 keV and 500 keV, the depth of the peak of the relative dose can be present at not more than 100 μm from the upper major surface of the substrate 2.

In the second embodiment, the peak depth of the crystal lattice defect density can be in the vicinity of the upper major surface of the substrate 2 without using the mask composed of the absorber shown in the first embodiment. Thereby, in the same manner as in the first embodiment, the variation of lifetime-killer distribution can be suppressed. Therefore, change in breakdown voltage characteristics or change in breakdown-voltage leakage characteristics of the p-n junction provided in the substrate 2 can be suppressed. Further in the second embodiment, since the mask used in the first embodiment is not required, the manufacturing process can be simplified compared with the first embodiment.

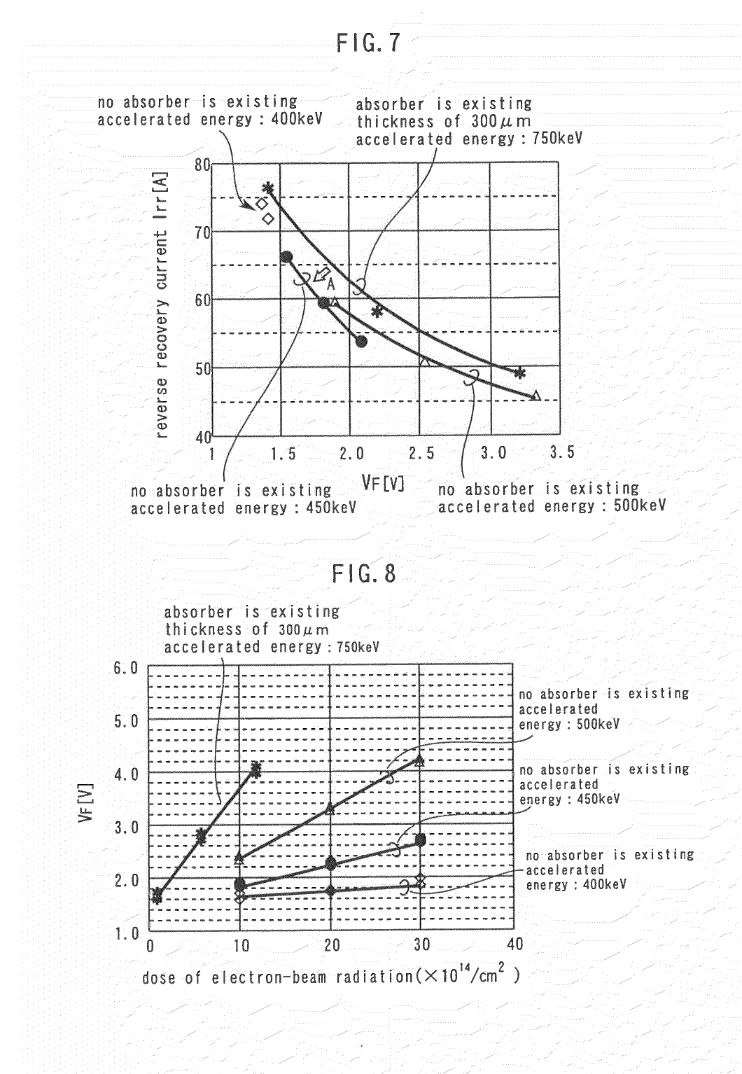

Next, the characteristics of the diode in the semiconductor device obtained in the First Embodiment and Second Embodiment will be described. FIG. 7 shows the tradeoff curves of the forward voltage drop Vf and the reverse recovery current of the diode. Here, the case wherein electron-beam radiation was performed with an accelerated energy of 750 keV after placing the mask composed of an absorber having a thickness of 300 μm on the upper major surface of the substrate 2; and the case wherein electron-beam radiation was performed with accelerated energies of 400 keV, 450 keV, and 500 keV without placing the above-described mask are shown.

As shown in FIG. 7, compared with the tradeoff curve in the case wherein electron-beam radiation was performed after placing the mask composed of an absorber having a thickness of 300 μm, when the accelerated energies were 400 keV, 450 keV, and 500 keV without placing the above-described mask, the tradeoff curves shifted in the A-direction (left below). From these results, it was confirmed that the characteristics of the diode were improved by performing electron-beam radiation with accelerated energies of 400 to 500 keV without placing the above-described mask as in the second embodiment, compared with performing electron-beam radiation using the above-described mask as in the first embodiment.

Next, the relationship between the dose of electron-beam radiation and the fall voltage Vf in the forward direction of the diode in the methods for manufacturing semiconductor devices obtained by the first and second embodiments will be described. As shown in FIG. 8, in electron-beam radiation, when a mask composed of an absorber having a thickness of 300 μm is used, change in Vf depending on the dose of electron beams is obtained. Whereas, when the above-described mask is not used, change in Vf relative to the dose of electron beams decreases with decrease in the accelerated energy of electron-beam radiation. When the accelerated energy is 400 keV, change in Vf becomes extremely small. From these results, when the accelerated energy is less than 400 keV, it is considered that change in Vf becomes extremely small even if the dose of electron beams is increased, and the desired lifetime control becomes difficult.

When the results of FIGS. 6 to 8 are considered, when electron-beam radiation is performed without using a mask composed of an absorber, the accelerated energy is preferably within a range between 400 and 500 keV. Thereby, change in the breakdown voltage characteristics of the p-n junction formed in the substrate can be minimized, the diode characteristics can be improved, and the carrier lifetime can be optimally controlled.

According to the method for the semiconductor device of the second embodiment, the peak depth of crystal lattice defect densities can be in the vicinity of the upper major surface of the substrate 2 without using the mask shown in the first embodiment. Thereby, in addition to the effects obtained in the first embodiment, the diode characteristics can be improved, and the method for manufacturing the semiconductor device can be simplified.

### Third Embodiment

A method for manufacturing a semiconductor device according to the third embodiment will be described. Here, the description will be focused on the aspects different from the first embodiment.

In the same manner as in the first embodiment, a semiconductor device 1 wherein a p-n junction is provided at the interface between a p-type diffusion layer region 5 and a low-concentration n-type impurity layer 3 in the vicinity of the upper major surface of a substrate 2 (refer to FIG. 2).

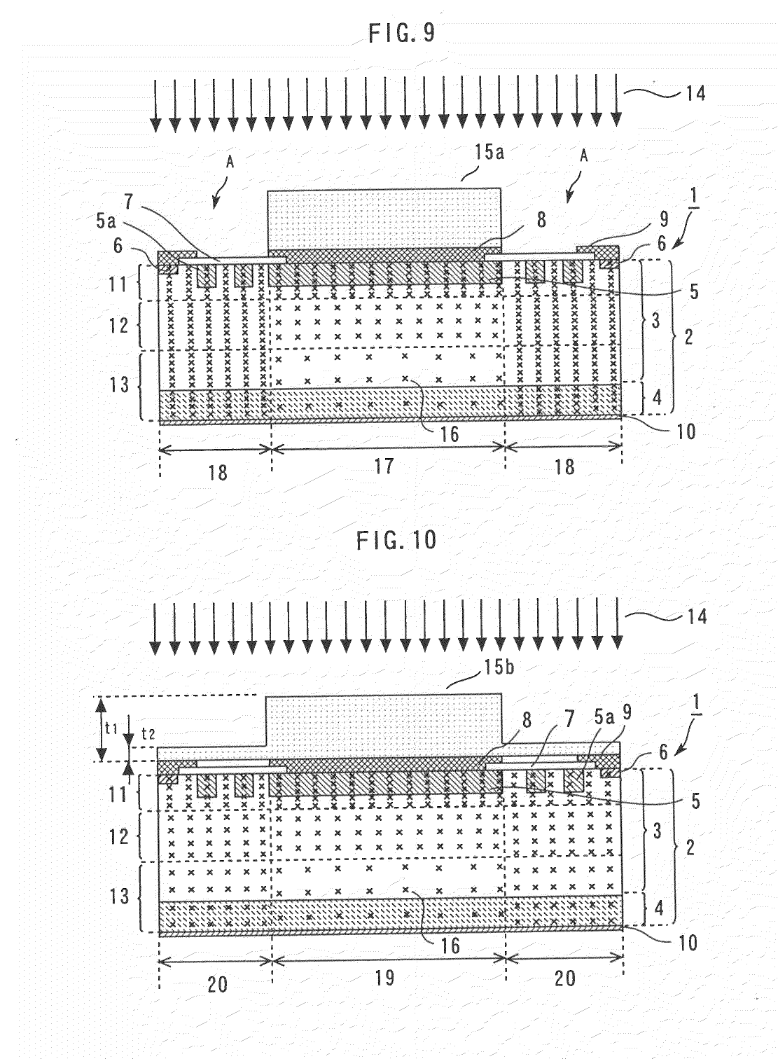

Next, as shown in FIG. 9, a mask 15a having an opening A is placed on the upper major surface of the substrate 2, and electron beams 14 are radiated through the mask 15a onto the upper major surface of the substrate 2. As the material for the mask 15a, a stainless steel having a specific gravity of 7.9 or the like is used. Thereafter, although not shown in the drawing, the semiconductor device is heat-treated in the same manner as in the first embodiment.

As a result, as shown in FIG. 9, in the location 17 of the semiconductor device 1, crystal lattice defects are distributed so that the crystal lattice defect densities are gradually decreased from the upper major surface toward the lower major surface of the substrate 2. In the location 18 of the semiconductor device 1, the depth of the peak of the crystal lattice defect densities from the upper major surface of the substrate 2 can be a desired value. Therefore, an element having desired diode characteristics (recovery characteristics, recovery tolerance) can be formed in a desired location in the semiconductor device 1.

According to the third embodiment, in addition to the effects obtained from the first embodiment, an element having desired diode characteristics can be formed in a desired location in the semiconductor device.

### Fourth Embodiment

A method for manufacturing a semiconductor device according to the fourth embodiment will be described. Here, the description will be focused on the aspects different from the first embodiment.

In the same manner as in the first embodiment, a semiconductor device 1 wherein a p-n junction is provided at the interface between a p-type diffusion layer region 5 and a low-concentration n-type impurity layer 3 in the vicinity of the upper major surface of a substrate 2 (refer to FIG. 2).

Next, as shown in FIG. 10, a mask 15b composed of an absorber is placed on the upper major surface of the substrate 2, electron beams 14 are radiated through the mask 15b onto the upper major surface of the substrate 2. At this time, the mask 15b has a region having a first thickness t₁ and a region having a second thickness t₂ thinner than the first thickness t₁. For example, the mask 15b has a region whose thickness t₁ is 100 μm, and a region whose thickness t₂ is 10 μm. Thereafter, although not shown in the drawing, the semiconductor device 1 is heat-treated in the same manner as in the first embodiment.

Thereby, the thickness of the absorber placed on the on the upper major surface of the location 20 is thinner than the thickness of the absorber placed on the upper major surface of the location 19 of the semiconductor device 1 shown in FIG. 10. Therefore, the peak of the crystal lattice defect densities from the upper major surface of the substrate 2 is deeper in the location 20 than in the location 19 of the semiconductor device 1. Specifically, the element can possess different diode characteristics (recovery characteristics, recovery tolerance) depending to the locations of the semiconductor device 1. Therefore, an element having desired diode characteristics in a desired location of the semiconductor device 1 can be formed.

According to the fourth embodiment, in addition to the effects obtained from the first embodiment, an element having different diode characteristics from other locations can be formed in a desired location in the semiconductor device.

Obviously many modifications and variations of the present invention are possible in the light of the above teachings. It is therefore to be understood that within the scope of the appended claims the invention may be practiced otherwise than as specifically described.

What is claimed is:

1. A method for manufacturing a semiconductor device comprising the steps of:
placing a mask for absorbing electron beams on a major surface of a semiconductor substrate having a p-n junction, and radiating electron beams onto the major surface of the semiconductor substrate at an accelerated energy of higher than 500 KeV to form crystal lattice defects in the semiconductor substrate; and
heat-treating the semiconductor substrate,
wherein an opening is formed in the mask, and material and/or thickness of the mask are chosen such that the electron beams are able to pass through the mask.
